(19) United States
(12) Patent Application Publication
(10) Pub. No.: US 2024/0177780 A1
(43) Pub. Date: May 30, 2024

(54) MEMORY DEVICE AND OPERATING METHOD OF THE MEMORY DEVICE

(71) Applicant: SK hynix Inc., Icheon-si Gyeonggi-do (KR)

(72) Inventor: Hee Youl LEE, Icheon-si Gyeonggi-do (KR)

(73) Assignee: SK hynix Inc., Icheon-si Gyeonggi-do (KR)

(21) Appl. No.: 18/326,781

(22) Filed: May 31, 2023

(30) Foreign Application Priority Data
Nov. 30, 2022 (KR) 10-2022-0164720

(51) Int. Cl. G11C 16/26; G11C 16/04; G11C 16/08; G11C 16/24

(52) U.S. Cl. CPC G11C 16/26; G11C 16/0433; G11C 16/08; G11C 16/24

(57) ABSTRACT

There are provided a memory device and an operating method of the memory device. The memory device includes: a plurality of pages each comprising a plurality of memory cells; a peripheral circuit for, in a read operation of a selected page among the pages, applying a read voltage to a selected word line connected to the selected page, sequentially applying sub-pass voltages and target pass voltages higher than the sub-pass voltages to adjacent word lines adjacent to the selected word line, and applying the target pass voltages to the other unselected word lines; and a control circuit for controlling the peripheral circuit. Before the read voltage is applied to the selected word line, the control circuit controls the peripheral circuit to apply the sub-pass voltages to the adjacent word lines, and apply the target pass voltages to the other unselected word lines.

### CROSS-REFERENCE TO RELATED APPLICATION

The present application claims priority under 35 U.S.C. § 119(a) to Korean patent application number 10-2022-0164720 filed on Nov. 30, 2022, in the Korean Intellectual Property Office, the entire disclosure of which is incorporated by reference herein.

### BACKGROUND

### 1. Technical Field

The present disclosure generally relates to a memory device and an operating method of the memory device, and more particularly, to a memory device configured to perform a read operation and an operating method of the memory device.

### 2. Related Art

A memory device may include a memory cell array in which data is stored, a peripheral circuit configured to perform a program, read or erase operation, and a control logic configured to control the peripheral circuit.

The memory cell array may include a plurality of memory blocks, and each of the plurality of memory blocks may include a plurality of memory cells. A memory device having a three-dimensional structure may include memory cells stacked above a substrate. For example, in the memory device having the three-dimensional structure, memory blocks may include a plurality of strings extending in a vertical direction from the substrate, and each of the plurality of strings may include a plurality of memory cells.

In a read operation of a selected memory block among the plurality of memory blocks, memory cells included in a selected page among a plurality of pages included in the selected memory block may be read. In the read operation, a read voltage may be applied to a selected word line connected to the selected page, and a pass voltage may be applied to the other unselected word lines.

### SUMMARY

In accordance with an embodiment of the present disclosure, there may be provided a memory device including: a plurality of pages each comprising a plurality of memory cells; a peripheral circuit configured to, in a read operation of a selected page among the plurality of pages, apply a read voltage to a selected word line connected to the selected page, sequentially apply sub-pass voltages and target pass voltages higher than the sub-pass voltages to adjacent word lines that are unselected word lines adjacent to the selected word line, and apply the target pass voltages to other unselected word lines different from the unselected word lines adjacent to the selected word line; and a control circuit configured to control the peripheral circuit, wherein, before the read voltage is applied to the selected word line, the control circuit controls the peripheral circuit to apply the sub-pass voltages to the adjacent word lines, and apply the target pass voltages to the other unselected word lines.

In accordance with an embodiment of the present disclosure, there may be provided a method of operating a memory device, the method including: dividing word lines into a selected word line, adjacent word lines that are unselected word lines adjacent to the selected word line, and other unselected word lines different from the unselected word lines adjacent to the selected word line; applying target pass voltages to the other unselected word line, and applying sub-pass voltages lower than the target pass voltages to the adjacent word lines; applying the target pass voltages to the adjacent word lines, after the sub-pass voltages are applied to the adjacent word lines; and applying a read voltage to the selected word line, when the target pass voltages are applied to the adjacent word lines.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device.

FIG. 2 is a diagram illustrating a memory block.

FIG. 3 is a diagram illustrating first adjacent word lines adjacent to a selected word line in a read operation in accordance with an embodiment of the present disclosure.

FIG. 4 is a flowchart illustrating a read operation in accordance with an embodiment of the present disclosure.

FIGS. 5A and 5B are diagrams illustrating a cause that the reliability of the read operation is deteriorated.

FIGS. 6A, 6B, and 6C are diagrams illustrating a channel length in accordance with the present disclosure.

FIG. 7 is a timing diagram illustrating a read operation in accordance with a first embodiment of the present disclosure.

FIG. 8 is a timing diagram illustrating a read operation in accordance with a second embodiment of the present disclosure.

FIG. 9 is a timing diagram illustrating a read operation in accordance with a third embodiment of the present disclosure.

FIG. 10 is a timing diagram illustrating a read operation in accordance with a fourth embodiment of the present disclosure.

FIG. 11 is a timing diagram illustrating a read operation in accordance with a fifth embodiment of the present disclosure.

FIG. 12 is a diagram illustrating adjacent word lines adjacent to a selected word line in read operations in accordance with sixth and seventh embodiments of the present disclosure.

FIG. 13 is a timing diagram illustrating the read operation in accordance with the sixth embodiment of the present disclosure.

FIG. 14 is a timing diagram illustrating the read operation in accordance with the seventh embodiment of the present disclosure.

FIG. 15 is a diagram illustrating a memory card system to which the memory device of the present disclosure is applied.

FIG. 16 is a diagram illustrating a Solid State Drive (SSD) system to which the memory device of the present disclosure is applied.

### DETAILED DESCRIPTION

The specific structural and functional descriptions disclosed herein are merely illustrative for the purpose of describing embodiments according to the concept of the present disclosure. Additional embodiments according to the concept of the present disclosure can be implemented in various forms. Thus, the present disclosure should not be construed as limited to the embodiments set forth herein.

Hereinafter, it will be understood that, although the terms “first,” “second,” etc. may be used herein to describe various elements, these elements should not be limited by these terms. These terms are only used to distinguish one element from another element. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

Various embodiments provide a memory device and an operating method of the memory device, which can improve the reliability of a read operation.

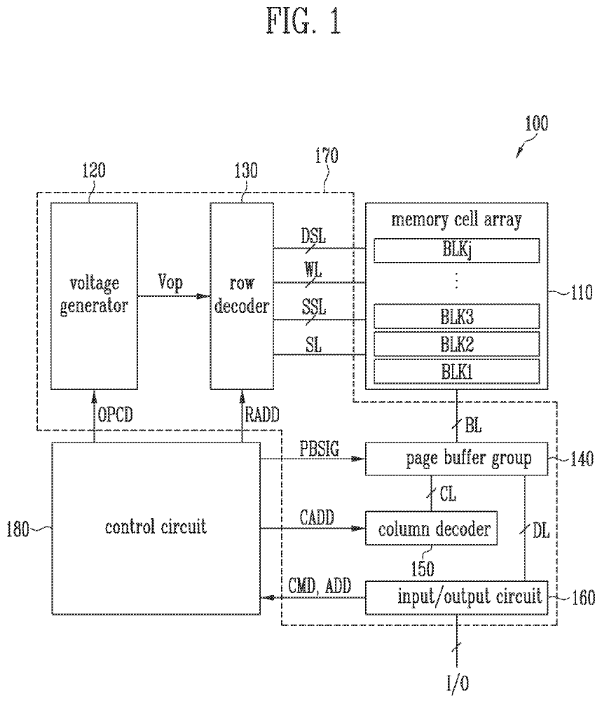

FIG. 1 is a diagram illustrating a memory device.

Referring to FIG. 1, the memory device 100 may include a memory cell array 110, a peripheral circuit 170, and a control circuit 180.

The memory cell array 110 may include first to jth memory blocks BLK1 to BLKj, wherein ‘j’ is a natural number greater than 2. Each of the first to jth memory blocks BLK1 to BLKj may include memory cells capable of storing data. Drain select lines DSL, word lines WL, source select lines SSL, and a source line may be connected to each of the first to jth memory blocks BLK1 to BLKj, and bit lines BL may be commonly connected to the first to jth memory blocks BLK1 to BLKj.

The first to jth memory blocks BLK1 to BLKj may be formed in a two-dimensional structure or a three-dimensional structure. Memory blocks having the two-dimensional structure may include memory cells arranged in parallel to a substrate. Memory blocks having the three-dimensional structure may include memory cells stacked in a vertical direction from a substrate. For convenience of description, the memory blocks formed in the three-dimensional structure are described in this embodiment. However, this embodiment may also be applied to the memory blocks having the two-dimensional structure.

The memory cells may store one-bit or two-or-more-bit data according to a program manner. For example, a manner in which one-bit data is stored in one memory cell is referred to as a single level cell (SLC) manner, and a manner in which two-bit data is stored in one memory cells is referred to as a multi-level cell (MLC) manner. A manner in which three-bit data is stored in one memory cell is referred to as a triple level cell (TLC) manner, and a manner in which four-bit data is stored in one memory cell is referred to as a quad level cell (QLC) manner. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 is configured to generate program voltages, turn-on voltages, turn-off voltages, negative voltages, precharge voltages, verify voltages, read voltages, pass voltages, and erase voltages in response to the operation code OPCD. The operating voltages Vop generated by the voltage generator 120 may be applied to drain select lines DSL, word lines WL, source select lines SSL, and a source line SL of a selected memory block through the row decoder 130.

The program voltages are voltages applied to a selected word line among word lines WL in a program operation, and may be used to increase a threshold voltage of memory cells connected to the selected word line. The turn-on voltages may be applied to the drain select lines DSL or the source select lines SSL, and be used to turn on drain select transistors or source select transistors. The turn-off voltages may be applied to the drain select lines DSL or the source select lines SSL, and be used to turn off the drain select transistors or the source select transistors. For example, the turn-off voltage may be set to 0V. The precharge voltages are voltages higher than 0V, and may be applied to the bit lines in a read operation. The verify voltages may be used in a verify operation for determining whether a threshold voltage of selected memory cells has been increased to a target level. The verify voltages may be set to various levels according to the target level, and be applied to a selected word line.

The read voltages may be applied to a selected word line in a read operation of selected memory cells. For example, the read voltages may be set to various levels according to a program manner of the selected memory cells.

The pass voltages are voltages applied to unselected word lines among the word lines WL in a program or read operation, and may be used to turn on memory cells connected to the unselected word lines. In the read operation in accordance with this embodiment, the pass voltages may include target pass voltages set highest and sub-pass voltages lower than the target pass voltages. For example, before a read voltage is applied to a selected word line, the sub-pass voltages may be applied to adjacent word lines adjacent to the selected word line. When the sub-pass voltages are applied to the adjacent word lines, the target pass voltages may be applied to the other unselected word lines. When the read voltage is applied to the selected word line, the target pass voltages may be applied to the adjacent word lines.

The erase voltages may be used in an erase operation for erasing memory cells included in a selected memory block, and be applied to the source line SL.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines, and may be connected to the first to jth memory blocks BLK1 to BLKj through the drain select lines DSL, the word lines WL, the source select lines SSL, and the source line SL.

The page buffer group 140 may include page buffers (not shown) connected to each of the first to jth memory blocks BLK1 to BLKj. The page buffers (not shown) may be connected to the first to jth memory blocks BLK1 to BLKj respectively through the bit lines BL. In a read operation, the page buffers (not shown) may sense a current or a voltage of the bit lines BL, which varies according to threshold voltages of selected memory cells, and store sensed data, in response to page buffer control signals PBSIG.

The column decoder 150 may be configured to transmit data between the page buffer group 140 and the input/output circuit 160 in response to a column address CADD. For example, the column decoder 150 may be connected to the page buffer group 140 through column lines CL, and transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit, to the control circuit 180, a command CMD and an address ADD, which are received from an external controller, through the input/output lines I/O, and transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output an operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation of a memory block selected by the address ADD. When the command CMD input to the control circuit 180 is a command corresponding to a read operation, the control circuit 180 may control the peripheral circuit 170 to perform the read operation of the selected memory block and output read data. When the command CMD input to the control circuit 180 is a command corresponding to an erase operation, the control circuit 180 may control the peripheral circuit 170 to perform the erase operation of the selected memory block.

In the read operation in accordance with this embodiment, the control circuit 180 may control the voltage generator 120 and the page buffer group 140 according to an algorithm including a step of applying sub-pass voltages to adjacent word lines adjacent to a selected word line among unselected word lines and applying target pass voltages to the other unselected word lines, a step of applying a read voltage to the selected word line, a step of applying the target pass voltages to the adjacent word lines, and a step of discharging the selected word line, the adjacent word lines, and the other unselected word lines.

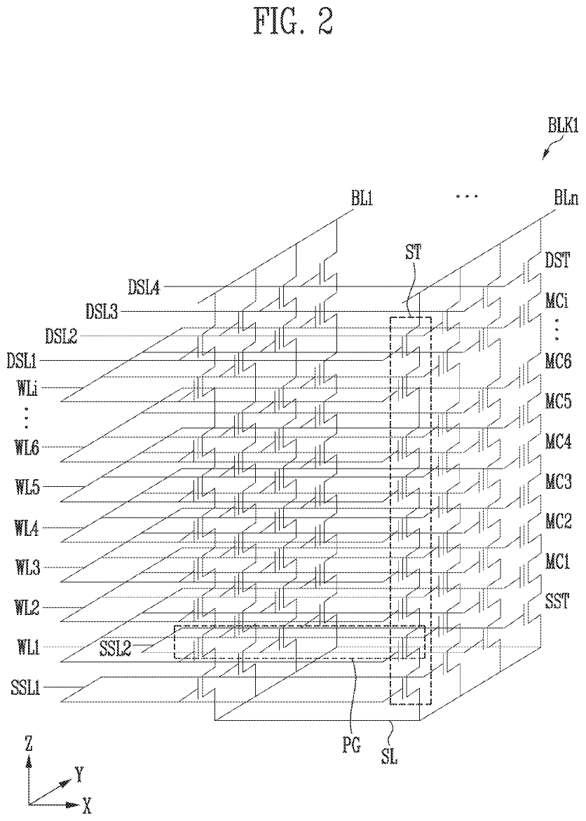

FIG. 2 is a diagram illustrating a memory block.

Referring to FIG. 2, the first to jth memory blocks BLK1 to BLKj shown in FIG. 1 are configured identically to one another, and therefore, the first memory block BLK1 among the first to jth memory blocks BLK1 to BLKj is illustrated in FIG. 2.

The first memory block BLK1 may include strings ST connected between first to nth bit lines BL1 to BLn and a source line SL. The first to nth bit lines BL1 to BLn extend along Y direction and are spaced apart from each other along an X direction. Therefore, the strings ST may extend along a Z direction and be spaced apart from each other along the X and Y directions.

Any one string ST among strings ST connected to the nth bit line BLn will be described as an example. The string ST may include a source select transistor SST, first to ith memory cells MC1 to MCi, and a drain select transistor DST. The first memory block BLK1 shown in FIG. 2 is a diagram schematically illustrating a structure of the memory block, and therefore, numbers of source select transistors SST, first to ith memory cells MC1 to MCi, and drain select transistors DST, which are included in the strings ST, may be changed according to a memory device.

Gates of source select transistors SST included in different strings ST may be connected to first and second source select lines SSL1 and SSL2, gates of first to ith memory cells MC1 to MCi included in the different strings ST may be connected to first to ith word lines WL1 to WLi, and gates of drain select transistors DST included in the different strings ST may be connected to first to fourth drain select lines DSL1 to DSL4.

Memory cells formed in the same layer among the first to ith memory cells MC1 to MCi may be connected to the same word line. For example, first memory cells MC1 included in different strings ST may be commonly connected to the first word line WL1, and ith memory cells MCi included in the different strings ST may be commonly connected to the ith word line WLi. A group of memory cells which are included in different strings ST and are connected to the same word line become a page PG. In the read operation in accordance with this embodiment may be performed in units of pages PG.

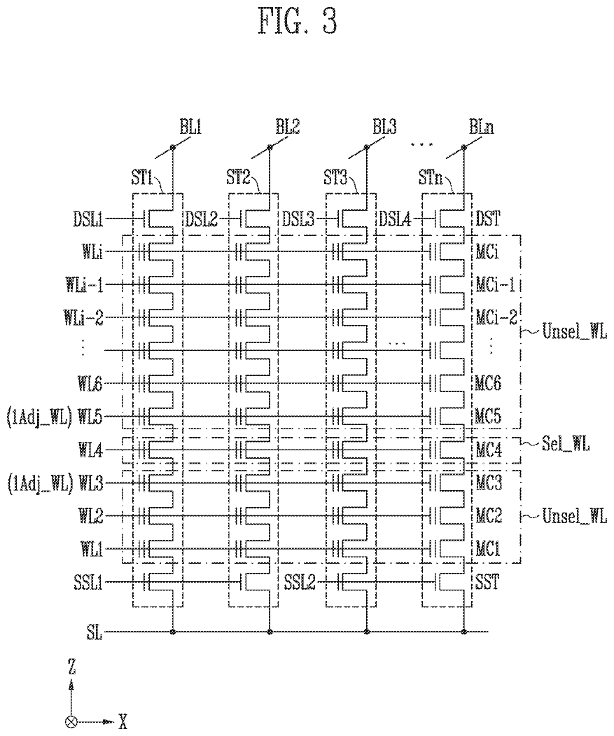

FIG. 3 is a diagram illustrating first adjacent word lines adjacent to a selected word line in a read operation in accordance with an embodiment of the present disclosure.

Referring to FIG. 3, it is assumed that first to ith word lines WL1 to WLi are connected to first to nth strings ST1 to STn selected by a first drain select line DSL1 and a first source select line SSL1. The first to nth strings ST1 to STn may be respectively connected to first to nth bit lines BL1 to BLn.

It is assumed that the fourth word line WL4 among the first to ith word lines WL1 to WLj is a selected word line Sel_WL, and the first to third word lines WL1 to WL3 and the fifth to ith word lines WL5 to WLi are unselected word lines Unsel_WL.

The third and fifth word lines WL3 and WL5 adjacent to the selected word line Sel_WL among the unselected word lines Unsel_WL may become first adjacent word lines 1ADj_WL. For example, when the first to ith word lines WL1 to WLj are stacked in the Z direction from a substrate, the third word line WL3 adjacent to the selected word line Sel_WL in a lower direction from the selected word line Sel_WL and the fifth word line WL5 adjacent to the selected word line Sel_WL in an upper direction from the selected word line Sel_WL may be set to the first adjacent word lines 1Adj_WL.

Therefore, when the ith word line WLi is a selected word line Sel_WL, the (i−1)th word line WL(i−1) adjacent to the ith word line WLi in the lower direction from the ith word line WLi and an (i+1)th word line WL(i+1) adjacent to the ith word line WLi in the upper direction from the ith word line WLi may be set to the first adjacent word lines 1Adj_WL.

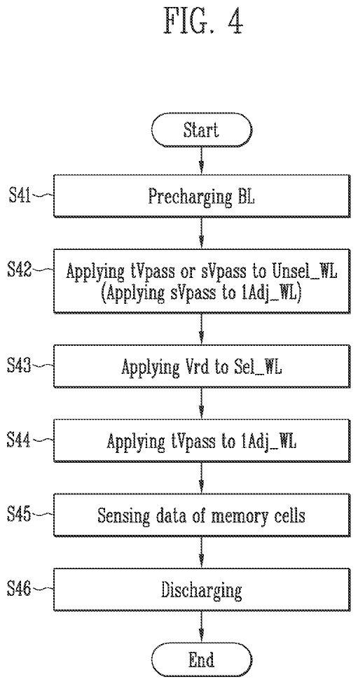

FIG. 4 is a flowchart illustrating a read operation in accordance with an embodiment of the present disclosure.

Referring to FIG. 4, when the read operation is started, bit lines BL connected to a selected memory block may be precharged to a positive voltage (S41).

Subsequently, target pass voltages tVpass or sub-pass voltages sVpass may be applied to unselected word lines Unsel_WL except a selected word line Sel_WL (S42). The sub-pass voltages sVpass lower than the target pass voltages tVpass may be applied to first adjacent word lines 1Adj_WL adjacent to the selected word line Sel_WL among the unselected word lines Unsel_WL. In the step S42, the selected word line Sel_WL may be floated, or a voltage of 0V may be applied to the selected word line Sel_WL. The target pass voltages tVpass may be set to a positive voltage at which unselected memory cells can all be turned on.

The sub-pass voltages sVpass may be set to a positive voltage at which first adjacent memory cells connected to the first adjacent word lines 1Adj_WL can be weakly turned on. The first adjacent memory cells may be memory cells adjacent to selected memory cells among the unselected memory cells. That the first adjacent memory cells are weakly turned on means that the first adjacent memory cells are turned on at a level lower than a level of the unselected memory cells turned on by the target pass voltage tVpass. When a turn-on level of memory cells is changed, an amount of current flowing through the memory cell may be changed. The sub-pass voltages sVpass may be set to a level which is lower than a level of the target pass voltages tVpass and is higher than a level of a read voltage Vrd.

When the target pass voltages tVpass or the sub-pass voltages sVpass are applied to the unselected word lines Unsel_WL, the read voltage Vrd may be applied to the selected word line Sel_WL (S43). The read voltage Vrd may be set according to logic page data programmed in memory cells. A read operation in a triple level cell (TLC) manner will be described as an example. The logical page data may be divided into least significant bit (LSB) data, central significant bit (CSB) data, and most significant bit (MSB) data. The read voltage Vrd may be set to any one of voltages corresponding to the LSB data, voltages corresponding to the CSB data, and voltages corresponding to the MSB data.

When the read voltage Vrd is applied to the selected word line Sel_WL, the target pass voltages tVpass may be applied to the first adjacent word lines 1Adj_WL (S44). For example, when the read voltage Vrd is applied to the selected word line Sel_WL in the step S43, the sub-pass voltages sVpass are applied to the first adjacent word lines 1Adj_WL. Therefore, in the step S44, the voltages applied to the first adjacent word lines 1Adj_WL may be increased from the sub-pass voltages sVpass to the target pass voltages tVpass.

When the read voltage Vrd is applied to the selected word line Sel_WL, and the target pass voltages tVpass are applied to all the unselected word lines Unsel_WL, a step of sensing data of memory cells connected to the selected word line Sel_WL may be performed (S45). For example, memory cells having a threshold voltage higher than the read voltage Vrd are turned off, and memory cells having a threshold voltage lower than the read voltage Vrd are turned on. Therefore, a voltage or a current of bit lines BL may be changed according to the turn-on or turn-off of the memory cells. The page buffer group may store data acquired by sensing the voltage or current of the bit lines BL.

When the data of the memory cells is sensed, the selected word line Sel_WL, the unselected word lines Unsel_WL, and the bit lines BL may be discharged (S46).

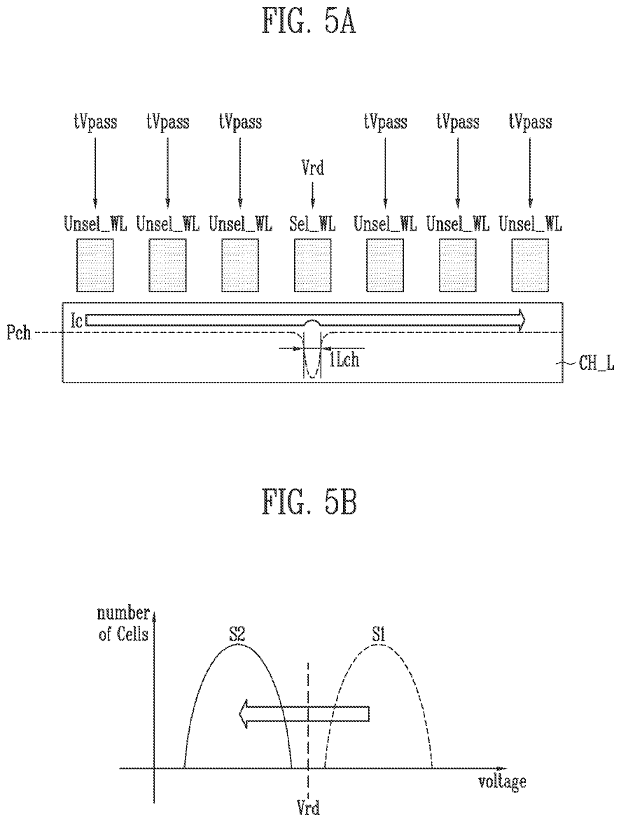

FIGS. 5A and 5B are diagrams illustrating a cause that the reliability of the read operation is deteriorated.

Referring to FIG. 5A, when the sub-pass voltages sVpass are not applied to the first adjacent word lines 1Adj_WL but the target pass voltages tVpass are applied to the first adjacent word lines 1Adj_WL in the step S42 shown in FIG. 4, a length of a channel region of a selected memory cell connected to the selected word line Sel_WL may be decreased to a first channel length 1Lch. In such a phenomenon, when the target pass voltages tVpass are applied to the other unselected word lines Unsel_WL except the selected word line Sel_WL, a channel potential Pch of a channel layer CH_L may be increased by the target pass voltages tVpass in the other region except a region in which the selected word line Sel_WL is formed. That is, since target pass voltages tVpass having a relatively large difference from the read voltage Vrd are applied to all the unselected word lines Unsel_WL located at both ends of the selected word line Sel_WL, the length of the channel region of the selected memory cell may be decreased to the first channel length 1Lch by the target pass voltages tVpass.

When a threshold voltage of the selected memory cell is lower than the read voltage Vrd, the selected memory cell is turned on regardless of the first channel length 1Lch. When the threshold voltage of the selected memory cell is higher than the read voltage Vrd, the selected memory cell is to be turned off. However, when the length of the channel region is shortened like the first channel length 1Lch, a channel may be weakly formed in the memory cell which is to be turned off, and therefore, a current Ic may flow. As described above, when the memory cell which is to be turned off is turned on, another data instead of data stored in the memory cell may be read. A case where another data instead of stored data is read will be described in detail as follows.

Referring to FIG. 5B, when a channel is formed in a memory cell in a first state S1 in which the memory cell has a threshold voltage higher than the read voltage Vrd, a current of a string may increase or a voltage of the string may decrease. When a sensing step of the memory cell is performed in this state, the memory cell may be sensed in a second state S2 lower than the first state S1, and therefore, the reliability of the read operation may be deteriorated.

In order to prevent or mitigate the deterioration of the reliability of the read operation, in the following embodiments, the sub-pass voltages sVpass lower than the target pass voltages tVpass may be applied to adjacent word lines adjacent to a selected word line. When the sub-pass voltages sVpass are applied to the adjacent word lines, a turn-on level of adjacent memory cells adjacent to a selected memory cell among unselected memory cells may be lowered. When the turn-on level of the adjacent memory cells is lowered, a channel length of the selected memory cell located between the adjacent memory cells may increase. Thus, a phenomenon in which a memory cell which is to be turned off in the read operation is turned on can be suppressed.

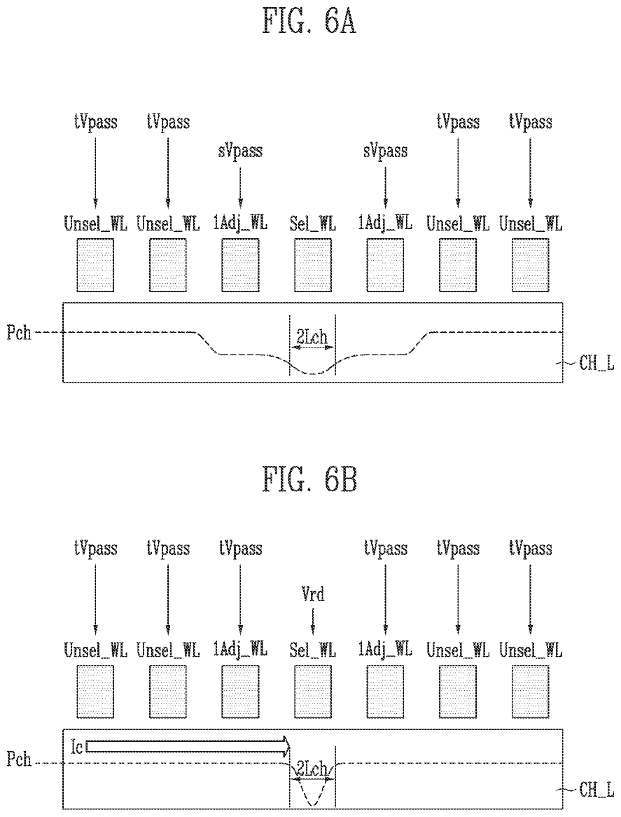

FIGS. 6A to 6C are diagrams illustrating a channel length in accordance with the present disclosure.

Referring to FIG. 6A, the sub-pass voltages sVpass lower than the target pass voltages tVpass may be applied to first adjacent word lines 1Adj_WL located at both ends of a selected word line Sel_WL, and the target pass voltages tVpass may be applied to the other unselected word lines Unsel_WL. When the sub-pass voltages sVpass are applied to the first adjacent word lines 1Adj_WL, a channel potential Pch of a channel layer CH_L in which the first adjacent word lines 1Adj_WL are formed may become lower than a channel potential Pch of a region in which the other unselected word lines Unsel_WL are formed. Therefore, a turn-on level of memory cells connected to the first adjacent word lines 1Adj_WL become lower than a turn-on level of memory cells connected to the other unselected word lines Unsel_WL. Hence, a length of a channel region of a memory cell connected to the selected word line Sel_WL may increase to a second channel length 2Lch longer than a first channel length 1Lch.

Referring to FIG. 6B, after the sub-pass voltages sVpass are applied to the first adjacent word lines 1Adj_WL as described above, a read voltage Vrd may be applied to the selected word line Sel_WL. When the read voltage Vrd is applied to the selected word line Sel_WL, the target pass voltages tVpass may be applied to the first adjacent word lines 1Adj_WL. As described with reference to FIG. 6A, although the target pass voltages tVpass are applied to all the unselected word lines Unsel_WL after a channel region having the second channel length 2Lch is secured in a selected memory cell, the channel length of the selected memory cell may be maintained as the second channel length 2Lch. That is, although the channel potential Pch of the channel layer CH_L is increased as the target pass voltages tVpass are applied to the first adjacent word lines 1Adj_WL, the channel region having the second channel length 2Lch is secured in the selected memory cell, and therefore, the channel length of the selected memory cell may be maintained as the second channel length 2Lch. Alternatively, although the channel potential Pch increases in the region in which the first adjacent word lines 1Adj_WL are formed due to the target pass voltages tVpass applied to the first adjacent word lines 1Adj_WL, a decrement of the second channel length 2Lch which has already been secured may be restrictive.

Referring to FIG. 6C, as described above, when the channel region having the second channel length 2Lch is formed in the selected memory cell, a memory cell in a first state S1 in which the memory cell has a threshold voltage higher than the read voltage Vrd may be sensed as data corresponding to the first state S1. Thus, in an embodiment, the reliability of the read operation of the memory device can be improved.

The method of applying the sub-pass voltages sVpass and the number of adjacent word lines to which the sub-pass voltages sVpass are applied may be variously changed. Various embodiments of this will be described as follows.

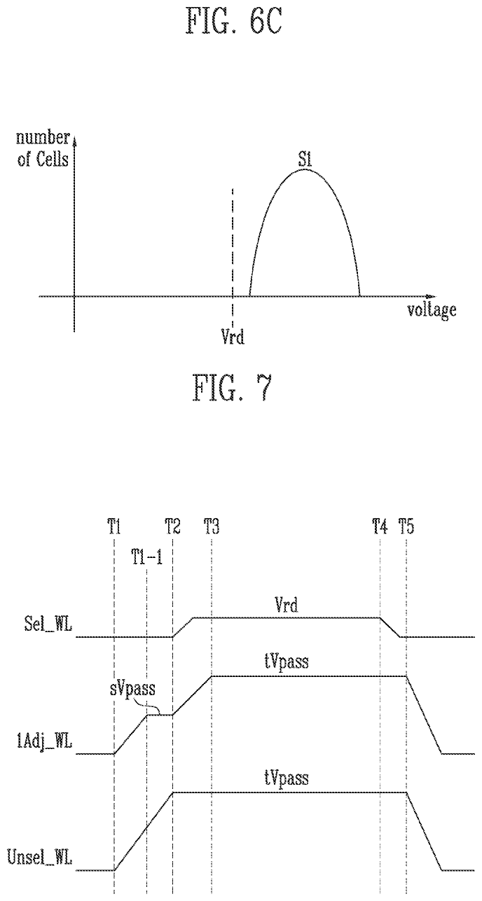

FIG. 7 is a timing diagram illustrating a read operation in accordance with a first embodiment of the present disclosure.

Referring to FIGS. 3 and 7, in a period T1 to T2, target pass voltages tVpass may be applied to the other unselected word lines Unsel_WL except the first adjacent word lines 1Adj_WL and the selected word line Sel_WL, and sub-pass voltages sVpass lower than the target pass voltages tVpass may be applied to the first adjacent word lines 1Adj_WL. The target pass voltages tVpass applied to the other unselected word lines Unsel_WL may be set to the same level or be set to different levels. The sub-pass voltages sVpass applied to the first adjacent word lines 1Adj_WL may be set to the same level or be set to different levels. When a string is formed in a vertical direction from a substrate, the first adjacent word lines 1Adj_WL may include one word line located under the selected word line Sel_WL and one word line located above the selected word line Sel_WL.

Since the sub-pass voltages sVpass are lower than the target pass voltages tVpass, a potential of the first adjacent word lines 1Adj_WL may be increased to a potential of the sub-pass voltages sVpass (T1−1), before a potential of the other unselected word lines Unsel_WL is increased to a potential of the target pass voltages tVpass (T2).

When the potential of the first adjacent word lines 1Adj_WL is increased to the potential of the sub-pass voltages sVpass (T1−1), the sub-pass voltages sVpass may be applied to the first adjacent word lines 1Adj_WL during a certain period T1−1 to T2 such that a channel region of a selected memory cell can be secured.

When the potential of the other unselected word lines Unsel_WL is increased to the potential of the target pass voltages tVpass (T2), the target pass voltages tVpass may be applied even to the first adjacent word lines 1Adj_WL, and the read voltage Vrd may be applied to the selected word line Sel_WL (T2 to T3).

In a period T3 to T4 in which the target pass voltages tVpass are applied to the other unselected word lines Unsel_WL and the first adjacent word lines 1Adj_WL and the read voltage Vrd is applied to the selected word line Sel_WL, a sensing step of selected memory cells may be performed.

When the sensing step is ended (T4), the selected word line Sel_WL may be discharged, and subsequently, the other unselected word lines Unsel_WL and the first adjacent word lines 1Adj_WL may be discharged (T5).

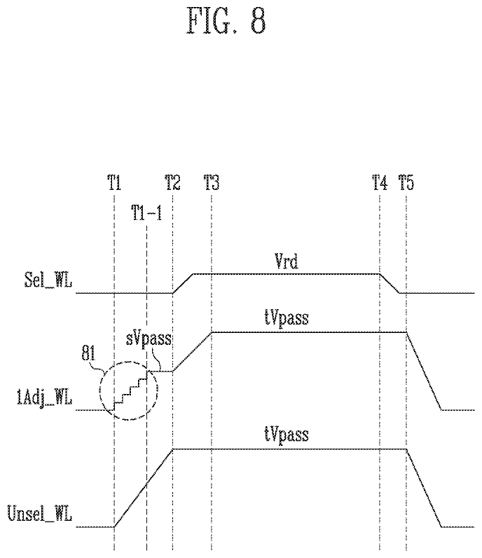

FIG. 8 is a timing diagram illustrating a read operation in accordance with a second embodiment of the present disclosure.

Referring to FIGS. 3 and 8, in a period T1 to T2, target pass voltages tVpass may be applied to the other unselected word lines Unsel_WL except the first adjacent word lines 1Adj_WL and the selected word line Sel_WL, and sub-pass voltages sVpass lower than the target pass voltages tVpass may be applied to the first adjacent word lines 1Adj_WL. When a string is formed in a vertical direction from a substrate, the first adjacent word lines 1Adj_WL may include one word line located under the selected word line Sel_WL and one word line located above the selected word line Sel_WL.

Since the sub-pass voltages sVpass are lower than the target pass voltages tVpass, a potential of the first adjacent word lines 1Adj_WL may be increased to a potential of the sub-pass voltages sVpass (T1−1), before a potential of the other unselected word lines Unsel_WL is increased to a potential of the target pass voltages tVpass (T2). During a period T1 to T1−1, the sub-pass voltages sVpass may be stepwisely increased in a stepped form (81).

When the potential of the first adjacent word lines 1Adj_WL is increased to the potential of the sub-pass voltages sVpass (T1−1), the sub-pass voltages sVpass may be applied to the first adjacent word lines 1Adj_WL during a certain period T1−1 to T2 such that a channel region of a selected memory cell can be secured.

When the potential of the other unselected word lines Unsel_WL is increased to the potential of the target pass voltages tVpass (T2), the target pass voltages tVpass may be applied even to the first adjacent word lines 1Adj_WL, and the read voltage Vrd may be applied to the selected word line Sel_WL (T2 to T3). In a period T2 to T3, the potential of the first adjacent lines 1Adj_WL may be linearly increased.

In a period T3 to T4 in which the target pass voltages tVpass are applied to the other unselected word lines Unsel_WL and the first adjacent word lines 1Adj_WL and the read voltage Vrd is applied to the selected word line Sel_WL, a sensing step of selected memory cells may be performed.

When the sensing step is ended (T4), the selected word line Sel_WL may be discharged, and subsequently, the other unselected word lines Unsel_WL and the first adjacent word lines 1Adj_WL may be discharged (T5).

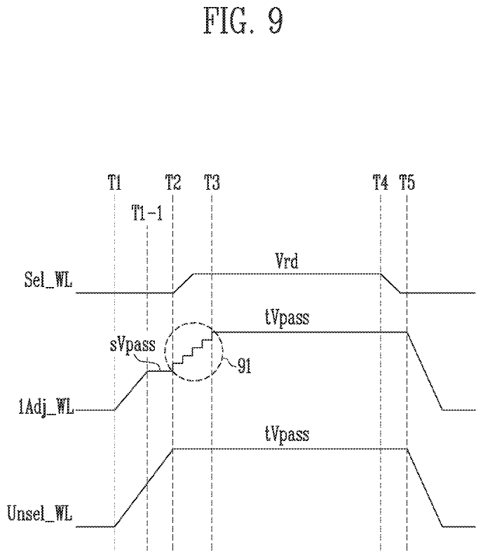

FIG. 9 is a timing diagram illustrating a read operation in accordance with a third embodiment of the present disclosure.

Referring to FIGS. 3 and 9, in a period T1 to T2, target pass voltages tVpass may be applied to the other unselected word lines Unsel_WL except the first adjacent word lines 1Adj_WL and the selected word line Sel_WL, and sub-pass voltages sVpass lower than the target pass voltages tVpass may be applied to the first adjacent word lines 1Adj_WL. In a period T1 to T1−1, the potential of the first adjacent word lines 1Adj_WL may be linearly increased. When a string is formed in a vertical direction from a substrate, the first adjacent word lines 1Adj_WL may include one word line located under the selected word line Sel_WL and one word line located above the selected word line Sel_WL.

Since the sub-pass voltages sVpass are lower than the target pass voltages tVpass, a potential of the first adjacent word lines 1Adj_WL may be increased to a potential of the sub-pass voltages sVpass (T1−1), before a potential of the other unselected word lines Unsel_WL is increased to a potential of the target pass voltages tVpass (T2).

When the potential of the first adjacent word lines 1Adj_WL is increased to the potential of the sub-pass voltages sVpass (T1−1), the sub-pass voltages sVpass may be applied to the first adjacent word lines 1Adj_WL during a certain period T1−1 to T2 such that a channel region of a selected memory cell can be secured.

When the potential of the other unselected word lines Unsel_WL is increased to the potential of the target pass voltages tVpass (T2), the target pass voltages tVpass may be applied even to the first adjacent word lines 1Adj_WL, and the read voltage Vrd may be applied to the selected word line Sel_WL (T2 to T3). In a period T2 to T3, the potential of the first adjacent lines 1Adj_WL may be stepwisely increased in a stepped form (91).

In a period T3 to T4 in which the target pass voltages tVpass are applied to the other unselected word lines Unsel_WL and the first adjacent word lines 1Adj_WL and the read voltage Vrd is applied to the selected word line Sel_WL, a sensing step of selected memory cells may be performed.

When the sensing step is ended (T4), the selected word line Sel_WL may be discharged, and subsequently, the other unselected word lines Unsel_WL and the first adjacent word lines 1Adj_WL may be discharged (T5).

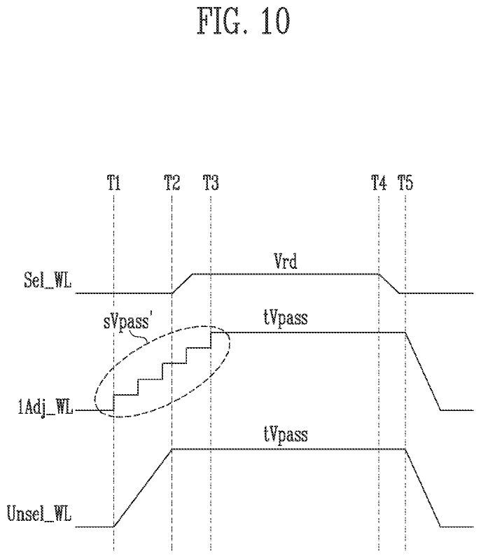

FIG. 10 is a timing diagram illustrating a read operation in accordance with a fourth embodiment of the present disclosure.

Referring to FIGS. 3 and 10, in a period T1 to T2, target pass voltages tVpass may be applied to the other unselected word lines Unsel_WL except the first adjacent word lines 1Adj_WL and the selected word line Sel_WL, and a plurality of sub-pass voltages sVpass' lower than the target pass voltages tVpass may be stepwisely applied in a stepped form to the first adjacent word lines 1Adj_WL. When a string is formed in a vertical direction from a substrate, the first adjacent word lines 1Adj_WL may include one word line located under the selected word line Sel_WL and one word line located above the selected word line Sel_WL.

When the potential of the other unselected word lines Unsel_WL is increased to the potential of the target pass voltages tVpass (T2) while the potential of the first adjacent word lines 1Adj_WL is increased to a potential of the sub-pass voltages sVpass' (T1 to T3), a read voltage Vrd may be applied to the selected word line Sel_WL (T2 to T3).

When the potentials of the other unselected word lines Unsel_WL and the first adjacent word lines 1Adj_WL are increased to the potential of the target pass voltages tVpass, and the read voltage Vrd is applied to the selected word line Sel_WL, a sensing step of selected memory cells may be performed in a period T3 to T4.

When the sensing step is ended (T4), the selected word line Sel_WL may be discharged, and subsequently, the other unselected word lines Unsel_WL and the first adjacent word lines 1Adj_WL may be discharged (T5).

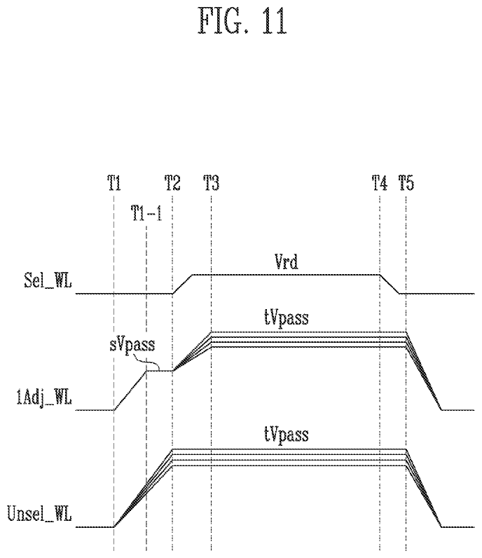

FIG. 11 is a timing diagram illustrating a read operation in accordance with a fifth embodiment of the present disclosure.

Referring to FIGS. 3 and 11, in a period T1 to T2, target pass voltages tVpass may be applied to the other unselected word lines Unsel_WL except the first adjacent word lines 1Adj_WL and the selected word line Sel_WL, and sub-pass voltages sVpass lower than the target pass voltages tVpass may be applied to the first adjacent word lines 1Adj_WL. The target pass voltages tVpass applied to the other unselected word lines Unsel_WL may be set to the same level regardless of positions of the other unselected word lines Unsel_WL, or be set to different levels according to the positions of the other unselected word lines Unsel_WL. For example, the target pass voltages tVpass having lower levels may be applied to the other unselected word lines Unsel_WL as the other unselected word lines Unsel_WL become more distant from the selected word line Sel_WL. When a string is formed in a vertical direction from a substrate, the first adjacent word lines 1Adj_WL may include one word line located under the selected word line Sel_WL and one word line located above the selected word line Sel_WL.

Since the sub-pass voltages sVpass are lower than the target pass voltages tVpass, a potential of the first adjacent word lines 1Adj_WL may be increased to a potential of the sub-pass voltages sVpass (T1−1), before a potential of the other unselected word lines Unsel_WL is increased to a potential of the target pass voltages tVpass (T2).

When the potential of the first adjacent word lines 1Adj_WL is increased to the potential of the sub-pass voltages sVpass (T1−1), the sub-pass voltages sVpass may be applied to the first adjacent word lines 1Adj_WL during a certain period T1−1 to T2 such that a channel region of a selected memory cell can be secured.

When the potential of the other unselected word lines Unsel_WL is increased to the potential of the target pass voltages tVpass (T2), the target pass voltages tVpass may be applied even to the first adjacent word lines 1Adj_WL, and the read voltage Vrd may be applied to the selected word line Sel_WL (T2 to T3). The target pass voltages tVpass applied to the first adjacent word lines 1Adj_WL may be set to the same level or be set to different levels. For example, the target pass voltages tVpass applied to the first adjacent word lines 1Adj_WL may be set equal to the target pass voltages tVpass applied to the other unselected word lines Unsel_WL.

In a period T3 to T4 in which the target pass voltages tVpass are applied to the other unselected word lines Unsel_WL and the first adjacent word lines 1Adj_WL and the read voltage Vrd is applied to the selected word line Sel_WL, a sensing step of selected memory cells may be performed.

When the sensing step is ended (T4), the selected word line Sel_WL may be discharged, and subsequently, the other unselected word lines Unsel_WL and the first adjacent word lines 1Adj_WL may be discharged (T5).

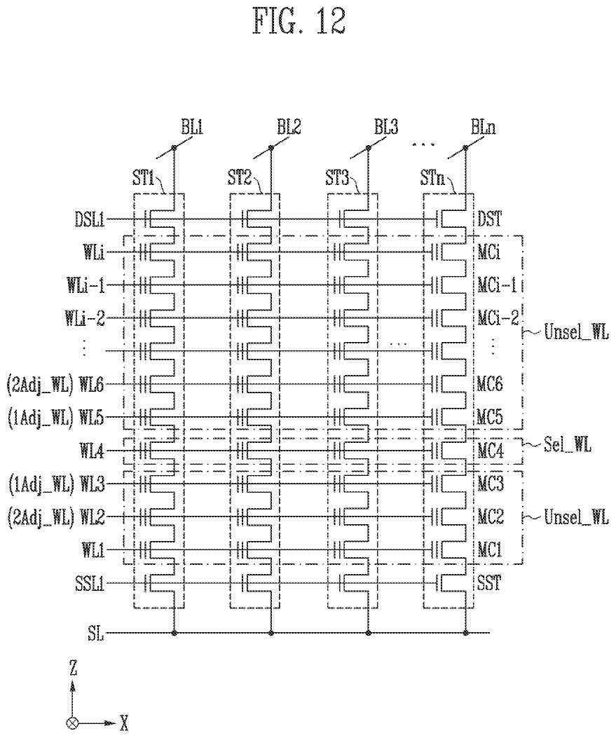

FIG. 12 is a diagram illustrating adjacent word lines adjacent to a selected word line in read operations in accordance with sixth and seventh embodiments of the present disclosure.

Referring to FIG. 12, in the read operations in accordance with the sixth and seventh embodiments of the present disclosure, a plurality of unselected word lines adjacent to the selected word line Sel_WL respectively under and above the selected word line Sel_WL may be set to adjacent word lines. For example, among the unselected word lines Unsel_WL, two unselected word lines adjacent to the selected word line Sel_WL respectively under and above the selected word line Sel_WL may be set to first adjacent word lines 1Adj_WL, and two unselected word lines respectively adjacent to the first adjacent word lines 1Adj_WL may be set to second adjacent word lines 2Adj_WL. That is, first unselected word lines adjacent to the selected word line Sel_WL respectively under and above the selected word line Sel_WL may become the first adjacent word lines 1Adj_WL, and second unselected word lines adjacent to the selected word line Sel_WL respectively under and above the selected word line Sel_WL may become the second adjacent word lines 2Adj_WL.

Although a case where two unselected word lines adjacent to the selected word line Sel_WL respectively under and above the selected word line Sel_WL become first and second adjacent word lines 1Adj_WL and 2Adj_WL has been illustrated in FIG. 12, the number of adjacent word lines may be changed to a larger number according to a memory device.

The read operations in accordance with the sixth and seventh embodiments of the present disclosure will be described as follows.

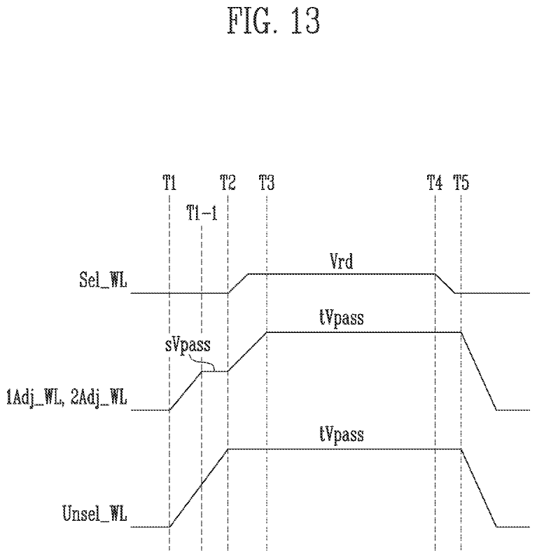

FIG. 13 is a timing diagram illustrating the read operation in accordance with the sixth embodiment of the present disclosure.

Referring to FIGS. 12 and 13, in a period T1 to T2, target pass voltages tVpass may be applied to the other unselected word lines Unsel_WL except the first and second adjacent word lines 1Adj_WL and 2Adj_WL and the selected word line Sel_WL, and sub-pass voltages sVpass lower than the target pass voltages tVpass may be simultaneously applied to the first and second adjacent word lines 1Adj_WL and 2Adj_WL. When a string is formed in a vertical direction from a substrate, the first and second adjacent word lines 1Adj_WL and 2Adj_WL may include word lines located under and above the selected word line Sel_WL. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Since the sub-pass voltages sVpass are lower than the target pass voltages tVpass, potentials of the first and second adjacent word lines 1Adj_WL and 2Adj_WL may be increased to a potential of the sub-pass voltages sVpass (T1−1), before a potential of the other unselected word lines Unsel_WL is increased to a potential of the target pass voltages tVpass (T2).

When the potentials of the first and second adjacent word lines 1Adj_WL and 2Adj_WL are increased to the potential of the sub-pass voltages sVpass (T1−1), the sub-pass voltages sVpass may be applied to the first and second adjacent word lines 1Adj_WL and 2Adj_WL during a certain period T1−1 to T2 such that a channel region of a selected memory cell can be secured.

When the potential of the other unselected word lines Unsel_WL is increased to the potential of the target pass voltages tVpass (T2), the target pass voltages tVpass may be applied even to the first and second adjacent word lines 1Adj_WL and 2Adj_WL, and a read voltage Vrd may be applied to the selected word line Sel_WL (T2 to T3).

In a period T3 to T4 in which the target pass voltages tVpass are applied to the other unselected word lines Unsel_WL and the first and second adjacent word lines 1Adj_WL and 2Adj_WL and the read voltage Vrd is applied to the selected word line Sel_WL, a sensing step of selected memory cells may be performed.

When the sensing step is ended (T4), the selected word line Sel_WL may be discharged, and subsequently, the other unselected word lines Unsel_WL and the first and second adjacent word lines 1Adj_WL and 2Adj_WL may be discharged (T5).

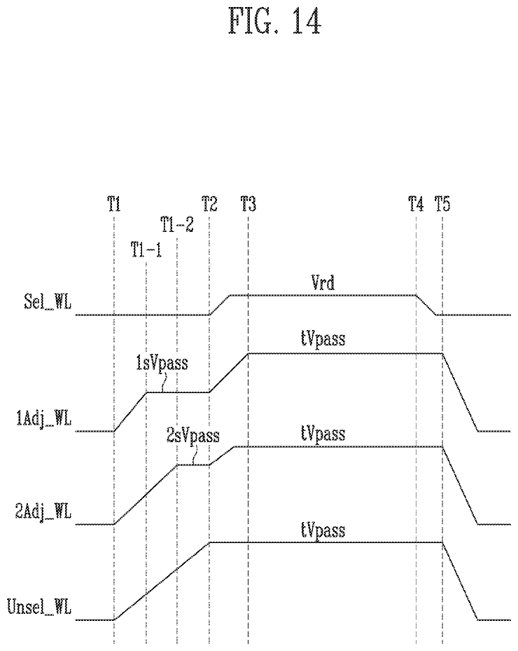

FIG. 14 is a timing diagram illustrating the read operation in accordance with the seventh embodiment of the present disclosure.

Referring to FIGS. 12 and 14, in a period T1 to T2, target pass voltages tVpass may be applied to the other unselected word lines Unsel_WL except the first and second adjacent word lines 1Adj_WL and 2Adj_WL and the selected word line Sel_WL, first sub-pass voltages 1sVpass lower than the target pass voltages tVpass may be applied the first adjacent word lines 1Adj_WL, and second sub-pass voltages 2sVpass between the target pass voltages tVpass and the first sub-pass voltages 1sVpass may be applied to the second adjacent word lines 2Adj_WL. That is, when a plurality of sub-pass voltages having different levels are used, relatively low sub-pass voltages may be applied to adjacent word lines close to the selected word line Sel_WL. In FIG. 14, since the first adjacent word lines 1Adj_WL among the first and second adjacent word lines 1Adj_WL and 2Adj_WL are closer to the selected word line Sel_WL than the second adjacent word lines 2Adj_WL, the first sub-pass voltages 1sVpass may be applied to the first adjacent word lines 1Adj_WL, and the second sub-pass voltages 2sVpass higher than the first sub-pass voltages 1sVpass may be applied to the second adjacent word lines 2Adj_WL.

Since the first and second sub-pass voltages 1sVpass and 2sVpass are lower than the target pass voltages tVpass, a potential of the first adjacent word lines 1Adj_WL may be increased to the first sub-pass voltages 1sVpass (T1−1), and subsequently, a potential of the second adjacent word lines 2Adj_WL may be increased to the second sub-pass voltages 2sVpass (T1−2), before a potential of the other unselected word lines Unsel_WL is increased to a potential of the target pass voltages tVpass (T2).

When the potential of the second adjacent word lines 2Adj_WL is increased to the potential of the second sub-pass voltages 2sVpass (T1−2), the first sub-pass voltages 1sVpass may be applied to the first adjacent word lines 1Adj_WL during a certain period T1−1 to T2 and the second sub-pass voltages 2sVpass may be applied to the second adjacent word lines 2Adj_WL during a certain period T1−2 to T2 such that a channel region of a selected memory cell can be secured.

When the potential of the other unselected word lines Unsel_WL is increased to the potential of the target pass voltages tVpass (T2), the target pass voltages tVpass may be applied even to the first and second adjacent word lines 1Adj_WL and 2Adj_WL, and a read voltage Vrd may be applied to the selected word line Sel_WL (T2 to T3).

When the target pass voltages tVpass are applied to the other unselected word lines Unsel_WL and the first and second adjacent word lines 1Adj_WL and 2Adj_WL, and the read voltage Vrd is applied to the selected word line Sel_WL, a sensing step of selected memory cells may be performed in a period T3 to T4.

When the sensing step is ended (T4), the selected word line Sel_WL may be discharged, and subsequently, the other unselected word lines Unsel_WL and the first and second adjacent word lines 1Adj_WL and 2Adj_WL may be discharged (T5).

In addition to the above-described first to seventh embodiments, various methods of applying sub-pass voltages lower than target pass voltages to adjacent word lines adjacent to a selected word line before a read voltage is applied to the selected word line may be performed.

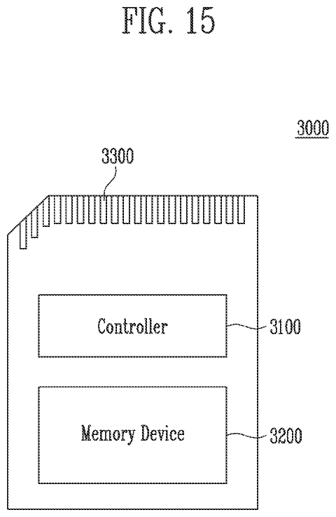

FIG. 15 is a diagram illustrating a memory card system to which the memory device of the present disclosure is applied.

Referring to FIG. 15, the memory card system 3000 includes a controller 3100, a memory device 3200, and a connector 3300.

The controller 3100 may be connected to the memory device 3200. The controller 3100 may access the memory device 3200. For example, the controller 3100 may control a program, read or ease operation, or control a background operation of the memory device 3200. The controller 3100 may provide an interface between the memory device 3200 and a host. The controller 3100 may drive firmware for controlling the memory device 3200. For example, the controller 3100 may include components such as a Random Access Memory (RAM), a processing unit, a host interface, a memory interface, and the error corrector.

The controller 3100 may communicate with an external device through the connector 3300. The controller 3100 may communicate with the external device (e.g., the host) according to a specific communication protocol. Exemplarily, the controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. Exemplarily, the connector 3300 may be defined by at least one of the above-described various communication protocols.

The memory device 3200 may include memory cells, and be configured identically to the memory device 100 shown in FIG. 1. Therefore, the memory device 3200 may adjust pass voltages applied to adjacent word lines adjacent to a selected word line in a read operation.

The controller 3100 and the memory device 3200 may be integrated into a single semiconductor device, to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

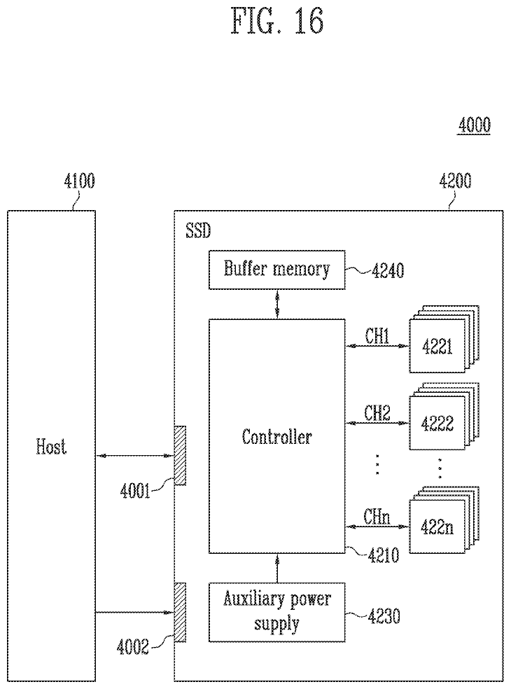

FIG. 16 is a diagram illustrating a Solid State Drive (SSD) system to which the memory device of the present disclosure is applied.

Referring to FIG. 16, the SSD system 4000 includes a host 4100 and an SSD 4200. The SSD 4200 exchanges a signal with the host 4100 through a signal connector 4001, and receives power through a power connector 4002. The SSD 4200 includes a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be a signal based on an interface between the host 4100 and the SSD 4200. For example, the signal may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. Therefore, each of the plurality of memory devices 4221 to 422n may adjust pass voltages applied to adjacent word lines adjacent to a selected word line in a read operation. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power PWR input from the host 4100 and charge the power PWR. When the supply of power from the host 4100 is not smooth, the auxiliary power supply 4230 may provide power of the SSD 4200. Exemplarily, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may temporarily store data received from the host 4100 or data received from the plurality of memory devices 4221 to 422n, or temporarily store meta data (e.g., a mapping table) of the memory devices 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

In accordance with an embodiment of the present disclosure, the reliability of a read operation performed in the memory device can be improved.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described examples of embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the examples of embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a plurality of pages each comprising a plurality of memory cells;
a peripheral circuit configured to, in a read operation of a selected page among the plurality of pages, apply a read voltage to a selected word line connected to the selected page, sequentially apply sub-pass voltages and target pass voltages higher than the sub-pass voltages to adjacent word lines that are unselected word lines adjacent to the selected word line, and apply the target pass voltages to other unselected word lines different from the unselected word lines adjacent to the selected word line; and
a control circuit configured to control the peripheral circuit,
wherein, before the read voltage is applied to the selected word line, the control circuit controls the peripheral circuit to apply the sub-pass voltages to the adjacent word lines, and apply the target pass voltages to the other unselected word lines.

2. The memory device of claim 1, wherein the peripheral circuit includes:
a voltage generator configured to generate and output the read voltage, the sub-pass voltages, and the target pass voltages; and
a page buffer group connected to the memory cells through bit lines to sense the memory cells.

3. The memory device of claim 1, wherein, after the target pass voltages are applied to the other unselected word lines, the control circuit controls the peripheral circuit to:
apply the read voltage to the selected word line; and
apply the target pass voltages to the adjacent word lines to which the sub-pass voltages are applied.

4. The memory device of claim 1, wherein the adjacent word lines are one or more adjacent lines adjacent to the selected word line respectively under and above the selected word line.

5. The memory device of claim 1, wherein the voltage generator stepwisely increases the sub-pass voltages applied to the adjacent word lines in a stepped form.

6. The memory device of claim 1, wherein the voltage generator stepwisely increases the target pass voltages applied to the adjacent word lines in a stepped form.

7. The memory device of claim 4, wherein the voltage generator applies the sub-pass voltages having the same level to the adjacent word lines.

8. The memory device of claim 7, wherein the voltage generator simultaneously applies the sub-pass voltages having the same level to the adjacent word lines.

9. The memory device of claim 4, wherein the voltage generator applies the sub-pass voltages having different levels to the adjacent word lines.

10. The memory device of claim 9, wherein the voltage generator applies the sub-pass voltages respectively to the adjacent word lines, and
wherein the sub-pass voltages are lowered as the respective adjacent word lines are closer to the selected word line.

11. The memory device of claim 9, wherein, after the voltage generator applies a highest voltage among the sub-pass voltages to the adjacent word lines, the voltage generator applies the target pass voltages to the adjacent word lines after a certain time.

12. The memory device of claim 11, wherein, the voltage generator simultaneously applies the read voltage to the selected word line when the voltage generator applies the target pass voltages to the adjacent word lines.

13. A method of operating a memory device, the method comprising:
dividing word lines into a selected word line, adjacent word lines that are unselected word lines adjacent to the selected word line, and other unselected word lines different from the unselected word lines adjacent to the selected word line;
applying target pass voltages to the other unselected word line, and applying sub-pass voltages lower than the target pass voltages to the adjacent word lines;
applying the target pass voltages to the adjacent word lines, after the sub-pass voltages are applied to the adjacent word lines; and
applying a read voltage to the selected word line, when the target pass voltages are applied to the adjacent word lines.

14. The method of claim 13, wherein the sub-pass voltages are stepwisely increased in a stepped form.

15. The method of claim 14, wherein the target pass voltages applied to the adjacent word lines are linearly increased.

16. The method of claim 13, wherein the sub-pass voltages are linearly increased.

17. The method of claim 16, wherein the target pass voltages applied to the adjacent word lines are stepwisely increased in a stepped form.

18. The method of claim 13, wherein, when a plurality of adjacent word lines among the adjacent word lines are disposed under the selected word line, and a plurality of adjacent word lines among the adjacent word lines are disposed above the selected word line, the sub-pass voltages having substantially the same level are applied to the adjacent word lines.

19. The method of claim 13, wherein the sub-pass voltages are simultaneously applied to the adjacent word lines.

20. The method of claim 13, wherein, when a plurality of adjacent word lines among the adjacent word lines are disposed under the selected word line, and a plurality of adjacent word lines among the adjacent word lines are disposed above the selected word line, the sub-pass voltage having different levels are applied to the adjacent word lines.

21. The method of claim 20, wherein the voltage generator applies the sub-pass voltages respectively to the adjacent word lines, and
wherein the sub-pass voltages are lowered as the respective adjacent word lines are closer to the selected word line.

22. The method of claim 20, wherein, after the voltage generator applies a highest voltage among the sub-pass voltages to the adjacent word lines, the voltage generator applies the target pass voltages to the adjacent word lines after a certain time.
